(19) United States
(12) Patent Application Publication
(10) Pub. No.: US 2004/0163765 A1
(43) Pub. Date: Aug. 26, 2004

(54) Plasma reactor for manufacturing electronic components

(75) Inventors: Kyung-Bin Bae, Pyungtaek-City (KR); Hee-Kook Park, Gangnam-Gu (KR)

Correspondence Address: WILLIAM J. SAPONE, COLEMAN SUDOL SAPONE P.C., 714 COLORADO AVENUE, BRIDGE PORT, CT, 06605, US

(73) Assignee: ANS Co., Ltd., Pyungtaek-City (KR)

(21) Appl. No.: 10/373,506

(22) Filed: Feb. 25, 2003

(51) Int. Cl. H01L 21/306

(52) U.S. Cl. 156/345.49

(57) ABSTRACT

The present invention relates to a plasma reactor for manufacturing electronic components which includes a reactor having a plasma generation region therein, and gas injection for injecting a reaction gas into the reactor. In the plasma reactor, a magnetic coil array unit is formed along an outer circumferential surface of the reactor, and a plurality of support members on which a coil is wound are installed along an outer circumferential surface of the reactor. A coil is wound onto each support member by a certain number of windings, and each magnetic coil is connected in series to each other in such a manner that the coils connected to neighboring support members have opposite polarities. The gas injector includes a gas spraying plate through which a gas is injected, and a separate gas spraying port formed in the gas spraying plate so that a main reaction gas and a mixing gas are sprayed along different paths.

### BACKGROUND OF THE INVENTION

1. Field of the Invention

The present invention relates to a plasma reactor for processing a wafer type material, and in particular to a plasma reactor which is capable of etching a certain material such as a semiconductor wafer and overcoming an unbalance of a plasma ion concentration in a center and edge portion of a wafer.

2. Description of the Background Art

FIG. 1A is a view illustrating a conventional plasma reactor for etching a wafer. As shown therein, in a reactive ion plasma reactor formed of two electrodes of a parallel flat plate structure, a reactor 3 includes a susceptor 5 which supports a wafer 4, and a distanced upper electrode 1. In the reactor 3, a main reaction gas and a mixing gas are sprayed through a gas spray plate 2. The susceptor 5 and the gas spraying plate 2 may be used as an electrode.

FIG. 1B is a view illustrating a gas injection unit formed of an upper electrode 1 and a gas spraying plate 2. A main reaction gas and a mixing gas are injected through gas injection ports 6g and 7g and pass through a gas mixing path 4g and are mixed therein. The mixed gas is injected into a reactor 3 through a gas spraying plate 2 and a gas spraying port 5g.

As shown in FIG. 3, in the above conventional plasma reactor, an unbalance phenomenon of a plasma ion concentration largely occurs in the interior of a reactor between a center portion and edge portion (portion A) of a wafer, so that it is impossible to implement a uniform etching ratio of a wafer.

In the conventional plasma reactor, in order to improve a non-uniformity of a plasma ion concentration and waferetching ratio, various methods are disclosed. Among the above methods, a few representative methods are shown in FIGS. 2A and 2B.

FIG. 2A is a view illustrating a method for forming a magnetic field in a plasma reactor. A plurality of permanent magnets 15 are installed in a circumferential portion of the reactor 13. Each permanent magnet has the same polarity as a neighboring permanent magnet, and each magnet has a uniform magnetic field direction. The sum of the entire magnetic fields is adjusted to pass a wafer surface in parallel. In a certain case, a permanent magnet array may be forcibly rotated at a uniform speed by a motor 11, so that a concentration and etching ratio of a plasma on a wafer are uniform in a reactor.

FIG. 2B is a view illustrating another method for forming a magnetic field in a plasma reactor. As shown therein, two pairs of large coils are installed in a circumferential portion of the reactor, so that magnetic fields Bx and By formed by the pairs of the coils pass through a surface of the wafer. The sum B of the magnetic fields are adjusted by the size of the DC current, so that it is possible to implement a certain rotation based on a uniform speed and phase on the wafer. It is performed such that each coil 1′, 2′, 3′ and 4′ is driven by each power driver 5′, 6′, 7′, and 8′, so that a uniform plasma concentration on the wafer is obtained based on a DC magnetic field.

However, in the above described methods, since the magnetic fields pass through the upper portion of the wafer, a conjugation portion may be damaged by a plasma during a pattern etching operation of a highly integrated semiconductor device, so that a critical device characteristic degradation may occur in a device of over 1 G DRAM. In addition, in the above methods, it is known that a non-uniformity of an etching ratio is not largely improved compared to a plasma reactor which does not includes a magnetic field.

### SUMMARY OF THE INVENTION

Accordingly, it is an object of the present invention to provide a plasma reactor for manufacturing electronic components which overcomes the problems encountered in the conventional art.

It is another object of the present invention to provide a plasma reactor for manufacturing electronic components which is capable of inducing a limited magnetic field in an inner portion of an inner wall of a reactor and an edge portion of a wafer for significantly improving a non-uniformity of a plasma ion concentration and etching ratio of a plasma reactor, different from a conventional method in which a rotation magnetic field which is formed by each separate coil passes through a wafer.

It is another object of the present invention to provide a plasma reactor for manufacturing electronic components by which a magnetic field is vibrated at a high speed by series-connected coils driven by a single power driver.

It is still another object of the present invention to provide a plasma reactor for manufacturing electronic components in which injection ports for gases injected into a reactor are separated based on their roles and forming a gas spraying plate in a multiple layer structure having multiple surfaces for increasing an operational effect.

It is still another object of the present invention to provide a plasma reactor for manufacturing electronic components which is capable of improving a non-uniformity of a plasma ion concentration between a center portion and an edge portion of a wafer and a wafer etching ratio.

To achieve the above objects, there is provided a plasma reactor which includes a coil array unit along a circumferential surface of a reactor for improving a non-uniformity of a plasma ion concentration and a wafer etching ratio between a center portion and any edge portion of a wafer. A magnetic coil array unit is driven by a series connected single power driver. An AC or pulse signal may be used as a single power driver.

In a magnetic coil array unit, a plurality of support members on which a coil is wound are installed along an outer circumferential surface of a reactor, and then a coil is wound on each support member by a certain number of turns. Each magnetic coil is connected in series in such a manner that the coils connected to a neighboring support members have opposite polarities. In addition, in a method for winding a coil, the coils are wound on a multiple layer structure and are arranged across from each other, so that a distribution of a magnetic field is adjusted based on a crossing area ratio.

The magnetic coil array unit preferably includes a cooling apparatus for removing heat which is generated in a magnetic coil. The above cooling apparatus includes a cooling water pipe inserted into a circumferential portion of a magnetic coil array unit for thereby circulating cooling water or a coolant therethrough.

In addition, in a plasma reactor according to the present invention, a gas injection unit includes a gas spraying plate through which a gas is sprayed. The gas spraying plate includes a separate gas spraying port such that a main reaction gas and mixing gas are sprayed through different paths.

The gas spraying plate is formed of a center plate of a center portion and an outer plate of an edge portion. The gas spraying port is formed in such a manner that the main reaction gas is sprayed to a center plate, and the mixing gas is sprayed to the outer plate.

The gas spraying plate is inclined in a boundary portion between the center plate and the outer plate, and the outer plate is thicker compared to the center plate. The gas spraying port may be formed in the inclined portion at a certain inclined angle.

The gas spraying port is formed in a center portion of the gas spraying plate based on a less dense method, and the gas spraying port is formed more densely in the direction of the edge portion.

### BRIEF DESCRIPTION OF THE DRAWINGS

The present invention will become better understood with reference to the accompanying drawings which are given only by way of illustration and thus are not limitative of the present invention, wherein;

FIG. 1A is a schematic cross-sectional view illustrating a conventional plasma reactor;

FIG. 1B is a cross-sectional view illustrating a gas injection portion of a conventional plasma reactor;

FIG. 1C is a plan view illustrating a gas spraying plate of a conventional plasma reactor;

FIG. 2A is a view illustrating a conventional plasma reactor in which a magnetic field of a double polar ring magnet is formed;

FIG. 2B is a view illustrating a conventional plasma reactor in which a magnetic field of a magnetic coil is formed;

FIG. 3 is a view illustrating a distribution of a plasma ion concentration of a conventional plasma reactor;

FIG. 4A is a schematic cross sectional view illustrating a plasma reactor according to the present invention;

FIG. 4B is a perspective view illustrating a plasma reactor according to the present invention;

FIGS. 5A and 5B are views illustrating a magnetic coil installation and a connection method of a magnetic coil according to the present invention;

FIGS. 5C, 5D and 5E are schematic views illustrating a magnetic characteristic based on a magnetic coil installation and a controller according to an embodiment of the present invention;

FIGS. 6A and 6B are views illustrating another embodiment of a coil installation method according to the present invention;

FIGS. 7A and 7B are views illustrating another embodiment of a coil installation method according to the present invention;

FIG. 8 is a cross-sectional view illustrating a gas injection portion according to an embodiment of the present invention;

FIGS. 9A and 9B are schematic views illustrating a gas spraying plate according to an embodiment of the present invention;

FIGS. 10A and 10B are schematic views illustrating an installation method of a spraying port of a gas spraying plate of a center portion according to an embodiment of the present invention; and

FIG. 11 is a view illustrating a distribution of a plasma ion concentration of an apparatus according to the present invention.

### DETAILED DESCRIPTION OF THE PREFERRED EMBODIMENTS

The preferred embodiments and operation of a plasma reactor according to the present invention will be explained with reference to the accompanying drawings.

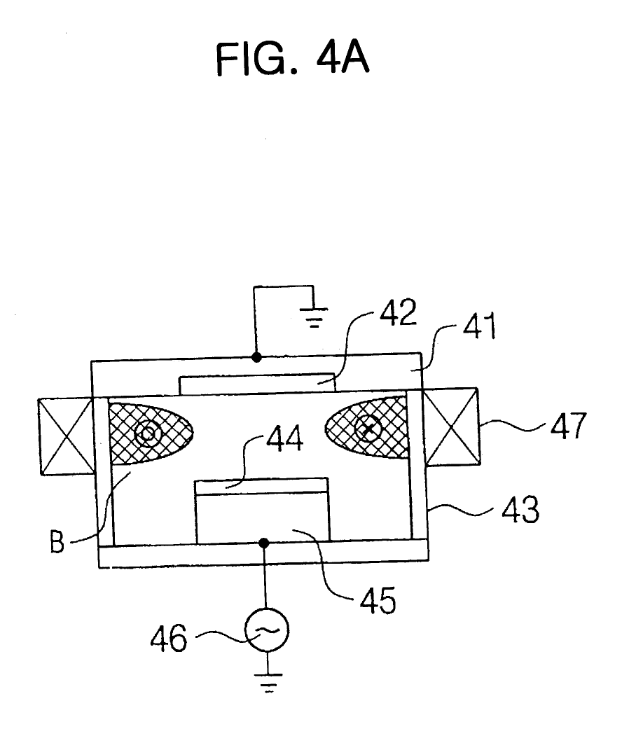

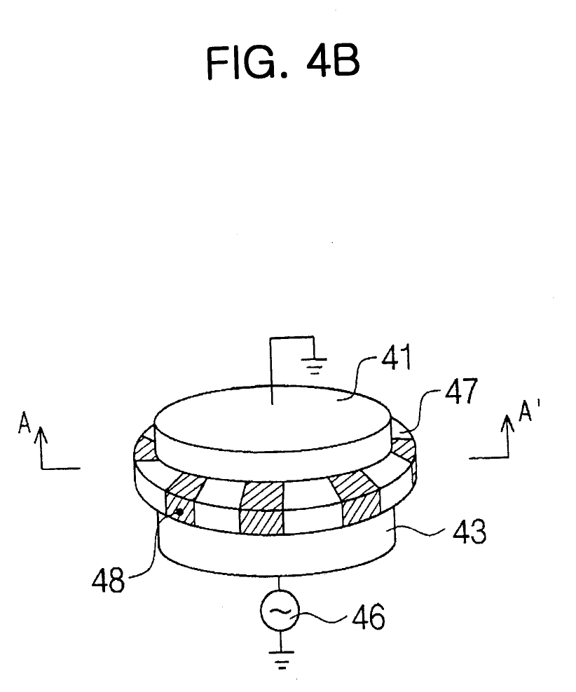

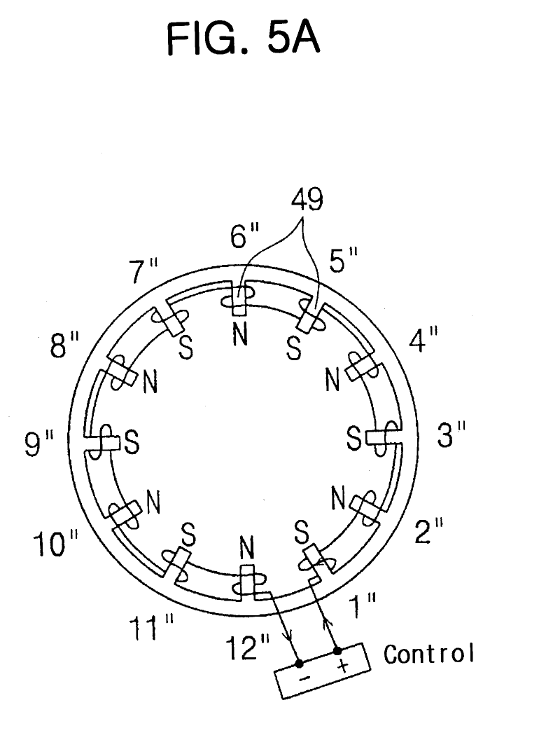

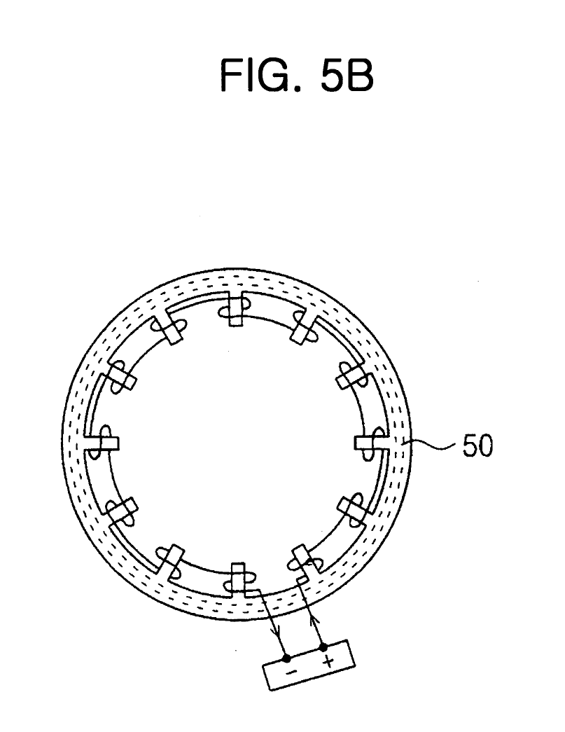

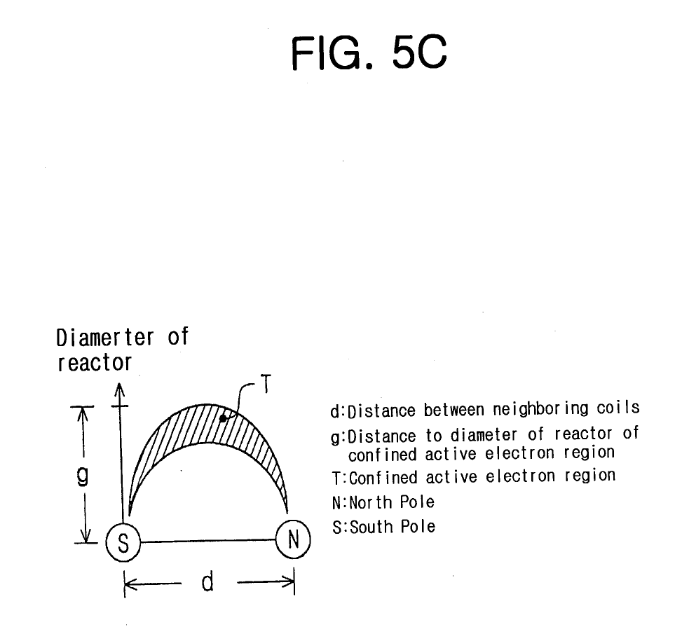

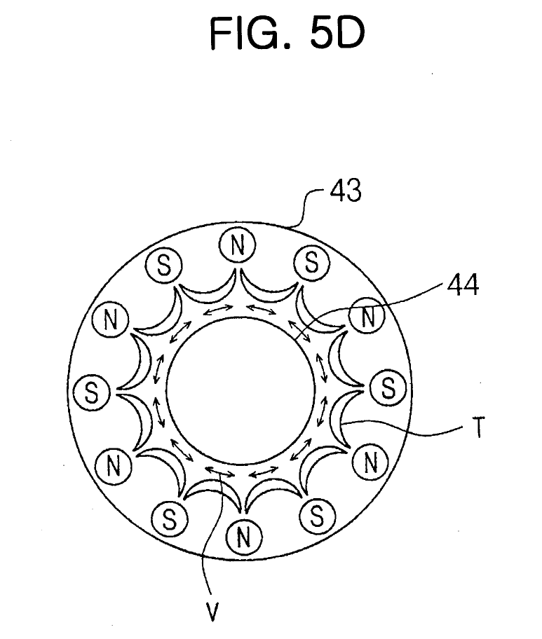

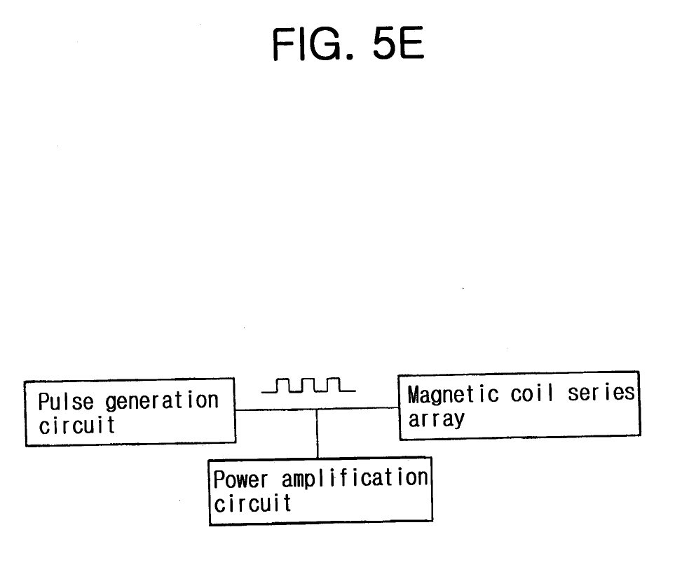

FIG. 4A is a cross-sectional view according to an embodiment of the present invention, FIG. 4B is a perspective view of the same, and FIG. 5A is a view illustrating a detailed construction of a magnetic coil array unit according to an embodiment of the present invention.

In the preferred embodiment of the present invention, a magnetic coil array unit 47 is installed in an outer circumferential surface of a reactor 43 for decreasing electrons which are moved to an inner wall of the reactor 43, and enhancing a plasma ion concentration in an edge portion of a wafer 44.

As shown in FIG. 5A, in the magnetic coil array unit 47, a plurality of support members 49 on which a coil is wound are formed. A coil is wound on each support member 49. Each coil is connected in series and is wound on each support member 49 in a reverse direction from each other coil by a certain number of turns so that a magnetic field of an opposite polarity with respect to a neighboring coil is formed.

Therefore, the direction of the magnetic field by each coil may be changed so that the polarity of each coil is alternately changed based on a wound direction of the magnetic coil. As shown in FIG. 5A, each magnetic coil is connected in series and is driven by one controller (power drive). The above construction of the magnetic coil is not limited thereto. In another embodiment of the present invention, the magnetic coils may be driven by winding in such a manner that neighboring magnetic coils vibrate.

Namely, as shown in FIG. 5C, the value of g may be adjusted so that a region in which electrons are confined between two neighboring magnetic coils is positioned in an edge portion of the wafer 44 based on the size of the current applied to each coil. Therefore, the plasma ionization in the above portion is increased by the active electrons in the above region.

As shown in FIG. 5D, the driving method of the magnetic coil array unit 47 may be driven, so that the magnetic coil array unit 47 is vibrated at a certain period and size at a high speed along an inner wall of the reactor 43 and an edge portion of the wafer 44 based on a driving method of the magnetic coil array unit 47, so that the plasma ion concentration in the side of the edge portion of the wafer 44 is increased, and the non-uniformity of the etching ratio is overcome. As shown in FIG. 5E, the above results may be obtained in such a manner that a current is sequentially applied to each magnetic coil by a single power driver based on an AC current or pulse signal. In this case, all coils are connected in series, so that the construction of a driving circuit is simplified.

A lot of heat may occur in the magnetic coil array unit 47 due to the plurality of magnetic coils. Since the ion distribution in a desired portion may be changed by the thusly occurred heat, as an example of a cooling apparatus, a cooling water pipe is installed in the interior of the support member of the magnetic coil array unit 47, so that a cooling water or coolant is circulated through the pipe. FIG. 5B is a view illustrating a magnetic coil array unit in which the cooling water pipe 50 is installed in the interior of the unit.

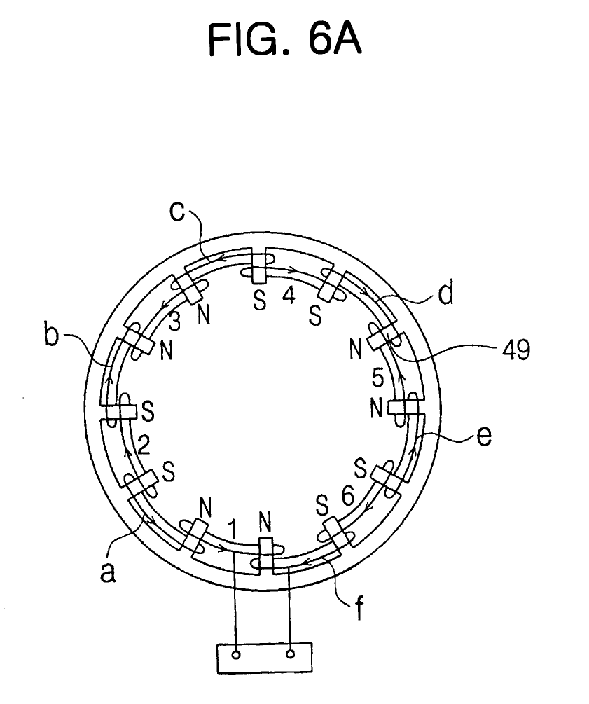

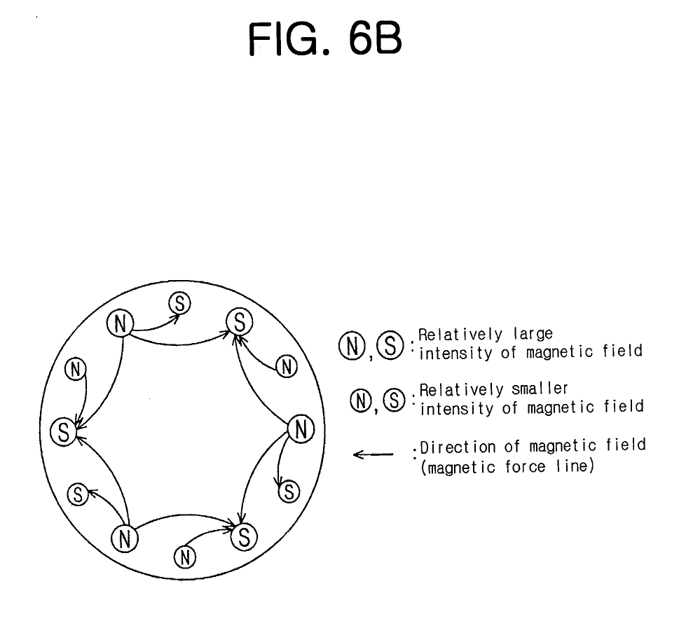

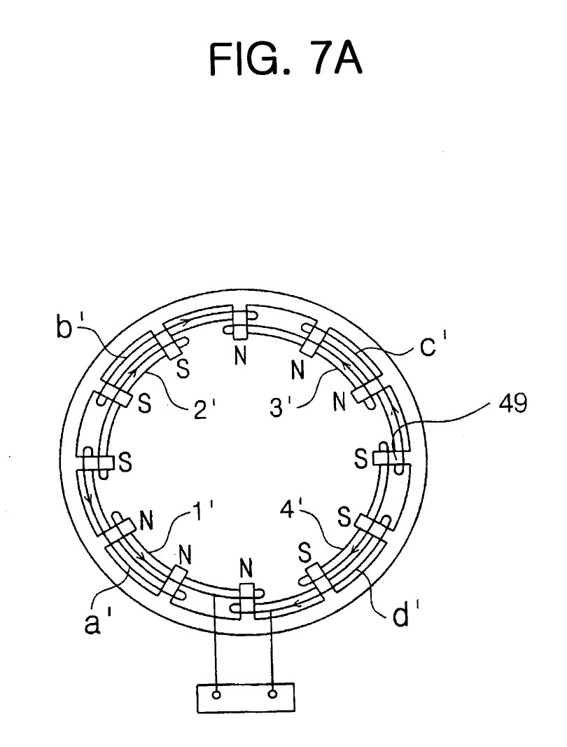

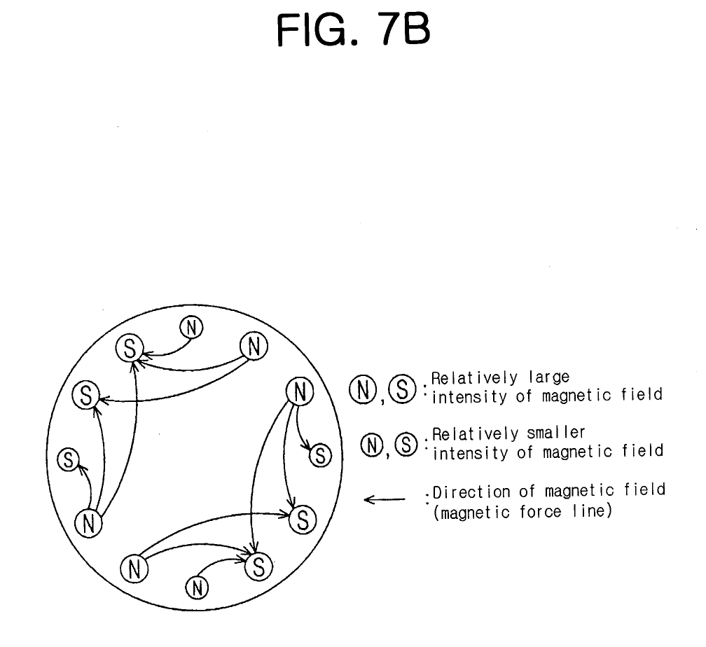

FIGS. 6A and 7A are views illustrating another embodiment of a method for winding a coil on a magnetic coil array unit 47. In the above embodiment of the present invention, it is possible to adjust the distribution of the magnetic field based on the area ratio in such a manner that the coils of the magnetic coil array unit 47 are crossingly formed in a multiple layer structure.

As shown in FIG. 6A, a plurality of support members 49 on which a coil is wound are installed, and a coil is wound on two neighboring support members in upper and lower directions in a two layer structure. Therefore, in this embodiment, neighboring coils of each layer are installed to have opposite polarities, and the coils 1, 2, 3, 4, 5 and 6 of the upper layer are installed in the direction of the wafer, and the coils a, b, c, d, e and f of the lower layer are installed in the side of the inner wall of the reactor. The winding sequence of the coils is 1-a-2-b-3-c-4-d-5-e-6-f. As shown in FIG. 6B, since there are polarities of N and S which each have a relatively large magnetic field distribution in the reactor based on the support members of the magnetic coil array unit 47 and polarities of N and S which each have a relatively small magnetic field distribution, the intensity of the magnetic field is not limited to the coils wound on the neighboring support member, so that a magnetic force line is widely distributed for thereby affecting the coils installed in two neighboring support members.

FIGS. 7A and 7B are views illustrating a magnetic coil array unit 47 according to another embodiment of the present invention. As shown therein, a plurality of support members 49 are installed for thereby winding coils thereonto. The coils formed in a two-layer structure are installed crossingly in an upper and lower direction in three neighboring support members. At this time, the coils 1′, 2′, 3′ and 4′ of the upper layer and the coils a′, b′, c′, and d′ of the lower layer are installed in the side of each wafer and the side of the inner wall of the reactor in such a manner that neighboring coils of each layer have opposite polarities. The winding sequence of the coils is 1′-a′-2′-b′-3′-c′-4′-d′. As shown in FIG. 7B, in the case of the magnetic field distribution in the interior of the interior, there are relatively large polarities of N and S. In addition, the direction and range of the magnetic field in the interior of the reactor are distributed in an inner portion of the inner wall of the reactor and an edge portion of the wafer by the above polarities. In addition, the active electron region is widely formed based on the distribution of the magnetic force line.

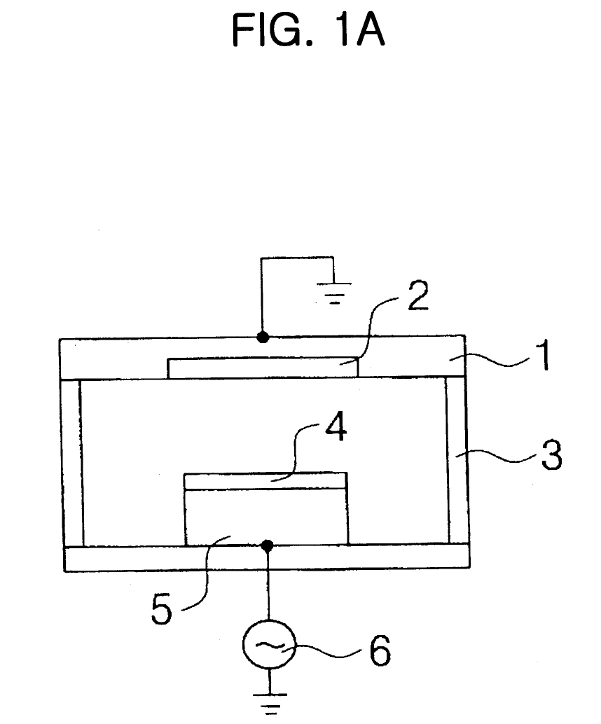

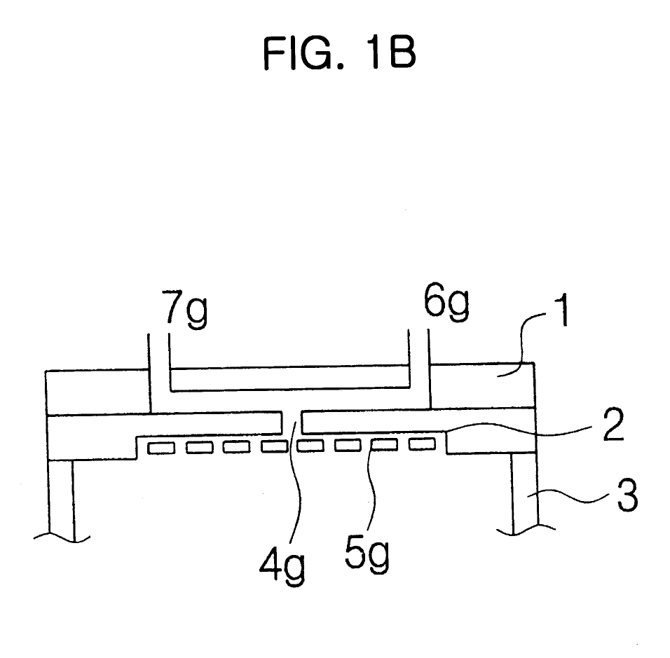

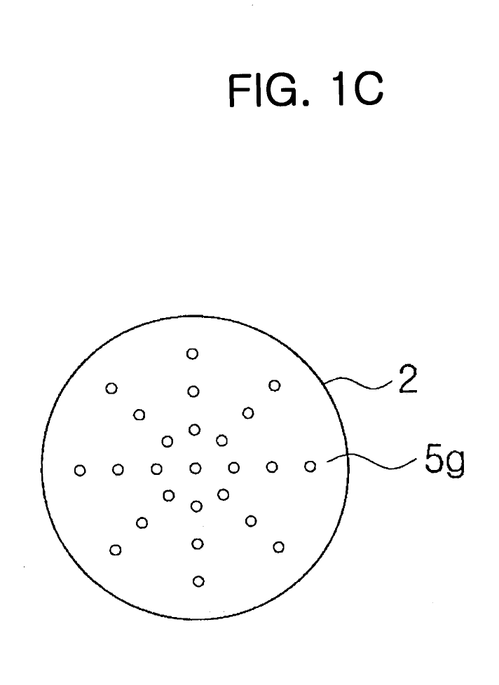

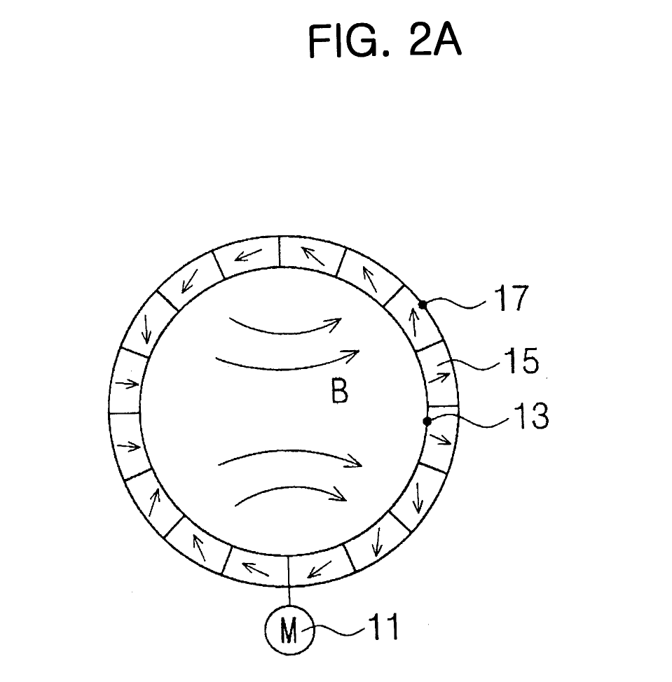

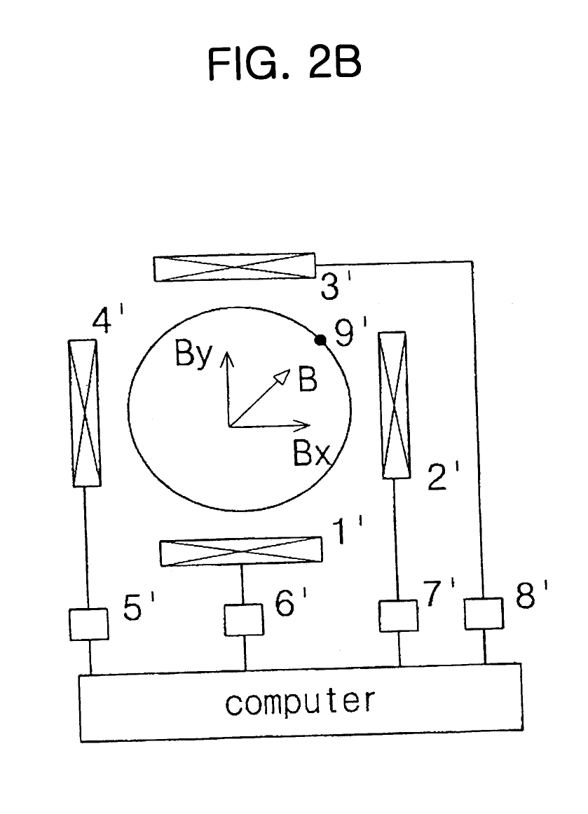

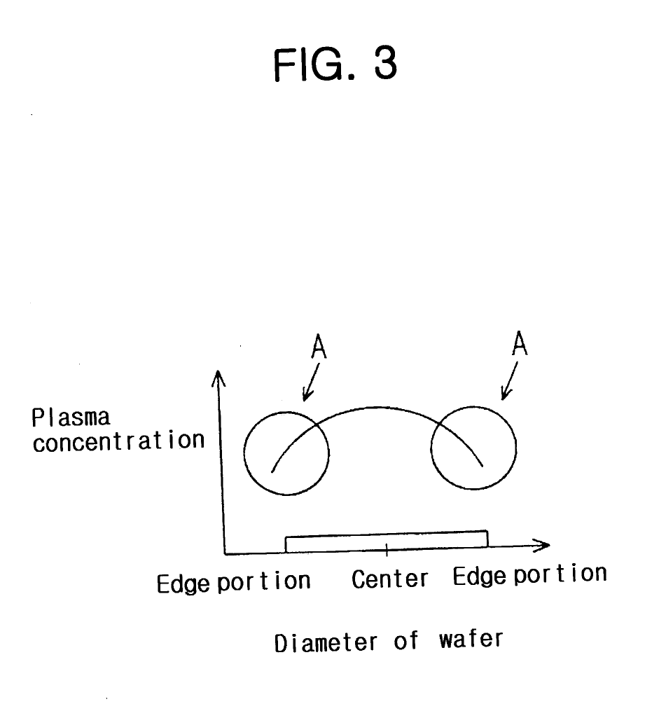

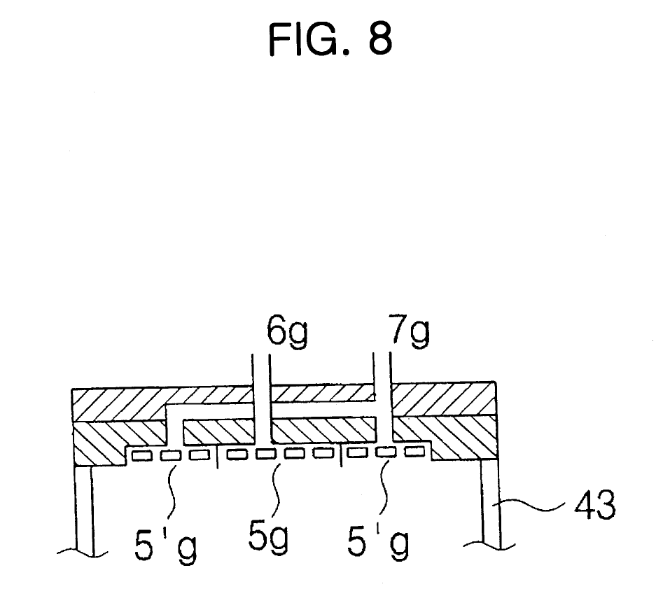

FIG. 8 is a cross sectional view illustrating a gas injection unit based on a preferred embodiment of the present invention. The embodiment of FIG. 8 is directed to maximizing the uniformity of the plasma ion concentration which is an object of the present invention. A main reaction gas and a mixing gas are injected through the gas injection unit. In the conventional plasma reactor, as shown in FIG. 1B, the main reaction gas and mixing gas are injected through each injection port 6g and 7g and are mixed in the mixing path 4g, and the mixed gas is flown into the reactor 3 through the gas spraying port 5g of the gas spraying plate.

In the preferred embodiment of the present invention, in order to overcome the non-uniformity problem of the plasma ion concentration, a gas spraying plate is improved. As shown in FIG. 8, a main reaction gas is sprayed to a center portion of the reactor 43 through the main reaction gas injection port 6g, and a mixing gas is sprayed to an inner side of an inner wall of the reactor and an edge portion of the wafer through the mixing gas injection port 7g, so that the mixing gas is fast spread in the direction of the center portion of the wafer based on a fast electron activation region of the edge portion of the wafer. As a result, the mixing gas is reacted more uniformly compared to the main reaction gas in the center portion of the wafer.

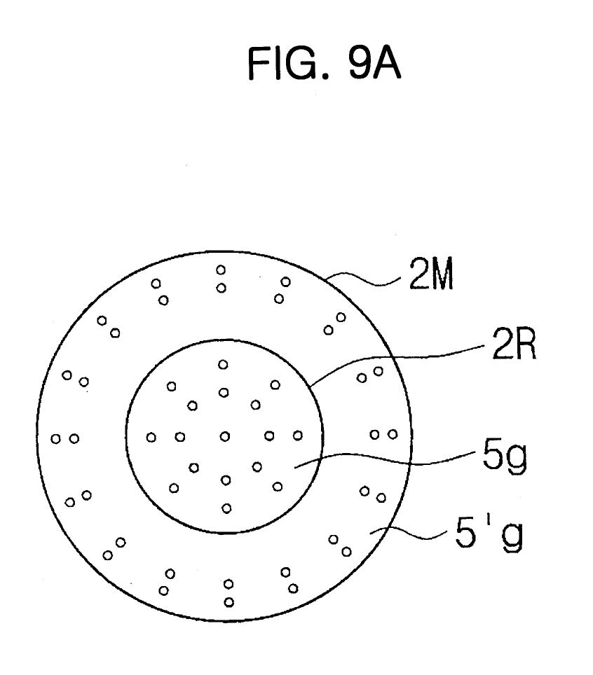

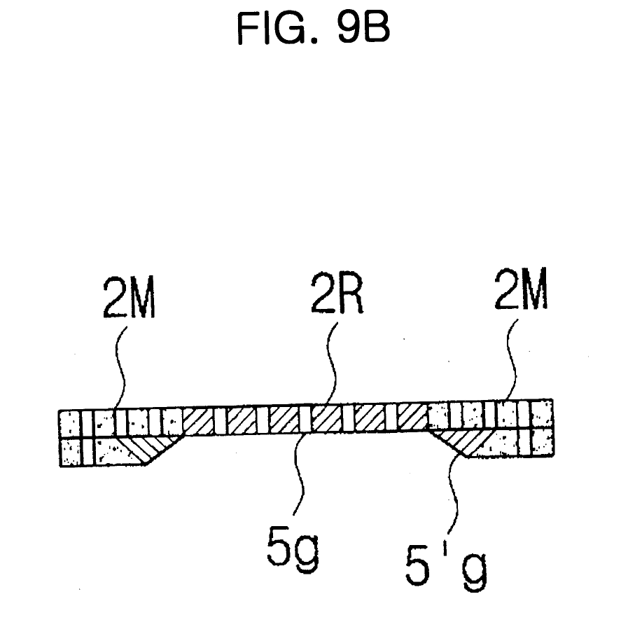

In the preferred embodiment of the present invention, as shown in FIGS. 9A and 9B, the gas spraying plate 42 is formed of a center plate 2R and an outer plate 2M. The main reaction gas is sprayed through the center plate 2R, and the mixing gas is sprayed through the outer plate 2M. In order to increase the efficiency, as shown in FIG. 9B, a certain step is formed at a certain angle in a portion of the outer plate 2M which contacts with the center plate 2R, so that the mixing gas is more efficiently mixed with the main reaction gas in a lower portion of the center plate 2R.

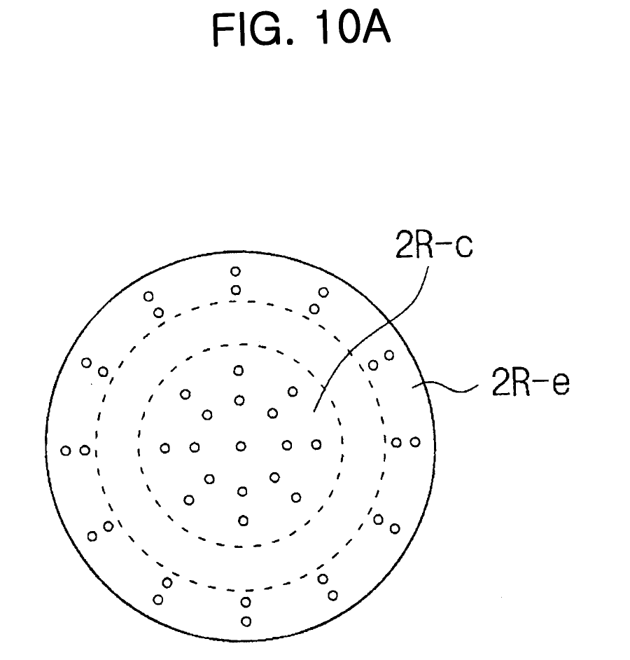

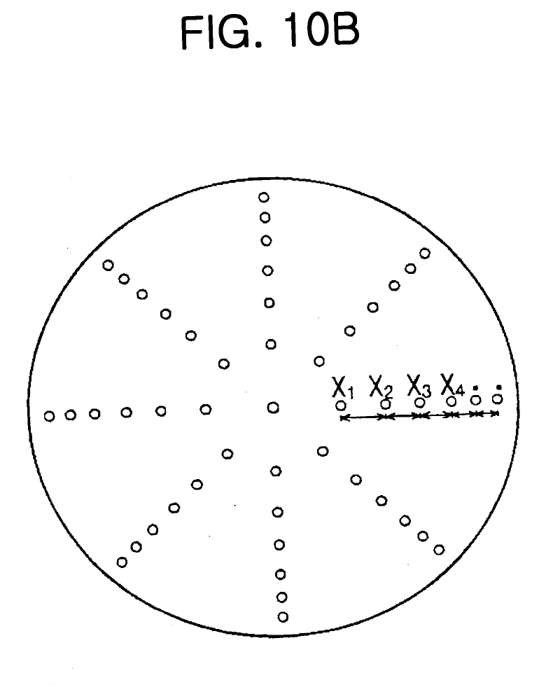

In addition, in the above embodiment of the present invention, one center plate 2R is formed. As shown in FIG. 10A, the spraying port may be formed in such a manner that the gas is injected into two regions, and the regions of the center plate 2R may be divided into multiple plate regions with respect to the co-axis of the center plate 2R, so that different main reaction gases of different kinds are sprayed. As shown in FIG. 10B, a certain method may be adapted. Namely, in the above new method, the number of the spraying ports is small in the center portion, and the number of the spraying ports is gradually increased in the direction of the edge portion. Therefore, the distance between the upper electrode and the wafer is decreased, and the effect of the operation is significantly increased based on the above method.

In the case that the present invention is used for an oxide film etching operation, as the main reaction gas, there are CF, CHF, NF and SF gases. As the mixing gas, there are He, Ar, 0₂, H₂, CO₂, etc. At this time, in the case that a certain gas having a high spreading characteristic like He is used as the mixing gas, the He ions injected into an edge portion of the reactor are fully accelerated based on an electron active layer and are dynamically reacted with the ions of CxFy and CxHyFz. Therefore, it is possible to significantly increase the ion concentration of the center portion of the wafer in the interior of the reactor and the edge portion of the wafer and increase the uniformity of the etching ratio.

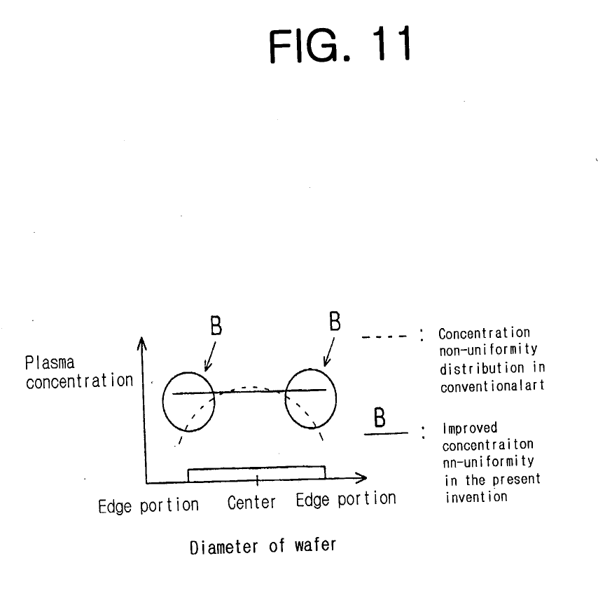

FIG. 11 is a view illustrating a region B in which the plasma concentration of the wafer and etching ratio are improved based on the mixing gas fast spread by the active electron layer.

As described above, an active electron layer which is fast vibrated at a high speed is formed in left and right portions of the edge portion of the wafer in such a manner that the polarities are different in the neighboring coils, and a plurality of coils are connected in series. In addition, the mixing gas is fast spread by changing the structure of the gas spraying plate, so that the ion concentration of the plasma ion in the center portion of the wafer and edge portion and the non-uniformity problem of the etching ratio are improved.

In addition, in the present invention, the magnetic coil array unit is driven by a single power driver such as AC or pulse signal, so that the construction of a driving circuit is simplified.

As the present invention may be embodied in several forms without departing from the spirit or essential characteristics thereof, it should also be understood that the above-described examples are not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

What is claimed is:

1. A plasma reactor which comprises a reactor having a plasma generation region therein, and a gas injection means for injecting a reaction gas into the reactor, a magnetic coil array unit formed along an outer circumferential surface of the reactor, and having a plurality of support members, on which a coil is wound, installed along an outer circumferential surface of the reactor, the coil wound onto each support member by a certain number of windings, and each magnetic coil being connected in series to each other in such a manner that the coils connected to neighboring support members have opposite polarities, said gas injection means including a gas spraying plate through which a gas is injected into the reactor, and having a separate gas spraying port formed in the gas spraying plate so that a main reaction gas and a mixing gas are sprayed through different ports.

2. The reactor of claim 1, wherein said coils of the magnetic coil array unit are formed in a multiple layer structure and are installed crosswise to each other, so that a distribution of a magnetic field is adjusted based on a crossing area ratio.

3. The reactor of claim 1, wherein said magnetic coil array unit is driven by an AC or pulse signal from a single power driver connected in series.

4. The reactor of claim 1, wherein said magnetic coil array unit is vibrated as a polarity between neighboring magnetic coils is changed.

5. The reactor of claim 1, further comprising:
a cooling apparatus installed in an interior of the magnetic coil array unit for circulating coolant therethrough.

6. The reactor of claim 1, wherein said gas spraying plate is formed of a center plate which is formed in a center portion of the gas spraying plate, a main reaction gas sprayed through the center plate and a mixing gas sprayed through an outer plate.

7. The reactor of claim 6, wherein said center plate is divided into a plurality of plate portions so that different main reaction gases are sprayed through each plate portion.

8. The reactor of claim 6, wherein said gas spraying plate has an outer plate that is thicker, having an inclined step portion in a boundary portion between the center plate and the outer plate, gas spraying ports in the outer plate inclined in a direction of a center portion of the gas spraying plate.

9. The reactor of claim 6, wherein said gas spraying ports are less densely formed in the center portion of the gas spraying plate, and are more densely formed in an edge portion thereof.
